(19) United States
(12) Patent Application Publication
(10) Pub. No.: US 2017/0049005 A1
(43) Pub. Date: Feb. 16, 2017

(54) GRAVITY ASSISTED COOLING SYSTEMS FOR DATA CENTERS

(71) Applicants: Anson Yen Chen, Atherton, CA (US); Kenneth Kyung Choi, Oakland, CA (US); John Gary Waclawsky, Alpine, WY (US)

(72) Inventors: Anson Yen Chen, Atherton, CA (US); Kenneth Kyung Choi, Oakland, CA (US); John Gary Waclawsky, Alpine, WY (US)

(21) Appl. No.: 14/823,888

(22) Filed: Aug. 11, 2015

(51) Int. Cl. H05K 7/20; F25D 1/02; B63B 35/00

(52) U.S. Cl. CPC H05K 7/20272; B63B 35/00; F25D 1/02; H05K 7/20236; H05K 7/20772; H05K 7/20781; H05K 7/2079

(57) ABSTRACT

Systems and methods are disclosed for cooling a computing facility housed in a structure surrounded by or nearby water. An inlet may and an outlet may be defined in a hull of a structure and a fluid path may extend between the inlet and outlet. The fluid path is configured to cool the computers of the computing facility as water from a body of water passes through the fluid path. The fluid path may include one or both of inlet and outlet siphons to draw water down into a basin positioned below the waterline. The fluid path between inlet and outlet may be closed and flow from inlet to outlet may be partially or completely driven by convection. Fluid flow may also be driven by gravity by placing an end of an outlet tube below the water line, such as adjacent a dam or other barrier bounding the body of water.

### FIELD OF THE INVENTION

This invention relates to systems and methods for cooling the large number of computer systems used in a data center.

### BACKGROUND OF THE INVENTION

Energy usage in Data Centers is a major cost consideration. Energy costs in data centers are due to computing activities that use energy and, as a byproduct, generate heat. Additional critical data center activities also use substantial amounts of energy because they are associated with heat management and removal. Using new technology for reducing computing energy use and controlling the processing, storage and data transmission activity of data center equipment is not the only way to increase power efficiency. The large majority of energy costs are associated with the efficient management and removal of heat from the data center. In fact, any active heat management equipment is substantially less than 100% efficient, which means heat monitoring and management equipment adds to the data center heat removal problem because they generate heat through their own operation.

### BRIEF DESCRIPTION OF THE DRAWINGS

In order that the advantages of the invention will be readily understood, a more particular description of the invention briefly described above will be rendered by reference to specific embodiments illustrated in the appended drawings. Understanding that these drawings depict only typical embodiments of the invention and are not therefore to be considered limiting of its scope, the invention will be described and explained with additional specificity and detail through use of the accompanying drawings, in which:

FIG. 1 is a schematic diagram of a cooling system for a data center housed within a floating structure in accordance with an embodiment of the present invention;

FIGS. 2A through 2C are schematic diagrams of alternative embodiments of a cooling system for a data center housed within a floating structure in accordance with an embodiment of the present invention;

FIG. 3 is a schematic diagram of an embodiment of a convective cooling system for a data center housed within a floating structure in accordance with an embodiment of the present invention;

FIGS. 4A and 4B are schematic diagrams of embodiments of a cooling system for a data center housed within a floating structure and located above the waterline in accordance with an embodiment of the present invention;

FIG. 5 is a schematic diagram of an embodiment of a cooling system for a data center housed within a floating structure and spanning the waterline in accordance with an embodiment of the present invention

FIG. 6 is a schematic diagram of an embodiment of a cooling system in a floating structure including dual fluid paths in accordance with an embodiment of the present invention; and

FIG. 7 is a schematic diagram of an embodiment for a cooling system for cooling a data center housed within a floating structure using dual fluid paths in accordance with an embodiment of the present invention.

### DETAILED DESCRIPTION

It will be readily understood that the components of the present invention, as generally described and illustrated in the Figures herein, could be arranged and designed in a wide variety of different configurations. Thus, the following more detailed description of the embodiments of the invention, as represented in the Figures, is not intended to limit the scope of the invention, as claimed, but is merely representative of certain examples of presently contemplated embodiments in accordance with the invention. The presently described embodiments will be best understood by reference to the drawings, wherein like parts are designated by like numerals throughout.

The invention has been developed in response to the present state of the art and, in particular, in response to the problems and needs in the art that have not yet been fully solved by currently available apparatus and methods. Accordingly, the invention has been developed to provide apparatus and methods for cooling a data center that is housed in a floating structure or other structure completely or partially surrounded by water.

In particular, a data center designed to take advantage of the close proximity of cool water and using natural processes as disclosed herein can provide a significant reduction in overall energy costs. Ultimately immersing a data center into a large heat sink such as a river, lake or ocean provides starting point for achieving a more efficient data center design and otherwise reducing energy usage. In some embodiments, in addition to immersing a data center in a heat sink, the methods disclosed herein take advantage of geographic surroundings and allow use of natural thermal and gravity driven processes.

In some embodiments, a modular physical design of a data center heat removal system is used. For example, a system may include multiple parts, which can be combined in some embodiments or modularized further in other embodiments. For example, in some embodiments, the system includes some or all of: 1) an adjustable gravity feed cold water system, 2) a distribution system for cold water, 3) a convection system to absorb and disperse heat, 4) natural occurring convection processes to expel hot air, 5) a gravity- and/or pump-driven hot water disposal system. Some or all of these components may be used to provide an efficient method of removing heat from a data center.

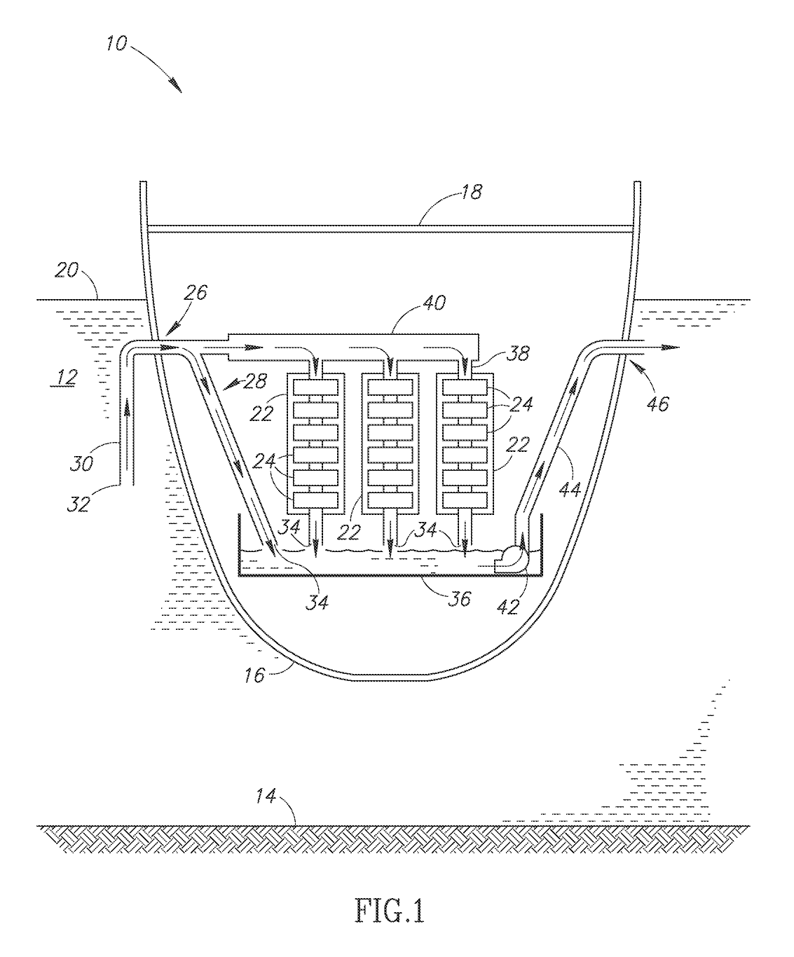

Referring to FIG. 1, a ship 10, or other floating structure, may float within a body of water 12, such as a river, lake or ocean. The body of water 12 defines a floor 14 and the ship may float above the floor 14 or rest on the floor 14. The ship 10 may include a hull 16 defining a watertight structure providing buoyancy to the ship 10 and one or more decks 18 for supporting cargo, crew etc. The ship 12 may include any structures that may be part of a ship, such as an engine, rudder, controls coupled to the engine and rudder, quarters for crew, and the like. The body of water 12 may define a waterline 20 and a portion of the hull 16 may be positioned below the waterline 20.

Water from the body of water 12 may be used to cool data center equipment. The equipment can be stand alone or mounted in racks 22 with each rack supporting a plurality of computing devices 24 such as servers, network components (routers, switches, storage, etc.), or other computing devices. The hull 16 may define an inlet 26 and water may flow into the inlet 26 and in some embodiments may follow a descending path 28 into the hull 16. The descending path 28 may be “closed” (e.g. a tube enclosing water flow) or “open”, e.g. a simple absence of obstructions to flow of water from the inlet 26. In this situation where the servers racks 22 and inlet port 26 are below the water line then water pressure will drive water into the ship and gravity will pull it down through the server racks 22 into the cooling basin 36 or directly into the cooling basin 36 where it can be used as a cool water source to cool the air.

In some embodiments, the descending path 28 may be defined by an inlet tube 30 having a first end 32 positioned outside of the hull 16 and one or more second ends 34 positioned inside the hull 16. Water 12 may be pushed by water pressure into the ship 10 from various depths by adjusting the position of the inlet 32 of the gravity feed tube 30 and the temperature of the water can be controlled by varying the depth of the end 32. The end 32 can vary in height between the height at the water line 20 and height at the location indicated by floor 14. Water that is deeper is colder. When the server racks 22 are partially or fully above the water line 20 and the end 32 is below the water line 20 and above the second ends 34, the input tube 30 becomes a siphon. This approach allows both water temperature and pressure to be controlled by varying the location of the end 32 relative to the second ends 34 or varying the location of the second ends relative to the first end 32. Alternately water can be obtained from any temperature depth and varying pressures by simply placing intake pipes through the boat hull at different depths. Either approach allows minimal moving parts once the flow of liquid is started.

The water can flow directly to a cooling basin 36 located at any specific level in the ship 10. Typically air cooled by the cooling basin will be drawn upwards within the equipment racks 22 and absorb the heat of nearby equipment and subsequently create a chimney effect of cold to hot air circulation. Alternately or in parallel, water can be simply routed through any number of water-cooling conduits 38 in or by each rack 22 or through any water-cooled standalone equipment. For example, the following discussion applies when the servers or computing equipment are above the water line. In that case, the conduits 38 may also function as part of the siphon 30 and lower ends thereof be second ends 34 of the siphon 30. Thus the conduits 38 may also facilitate the siphon and gravity feeding of water through the racks 22 into the basin 36. The rate of the water can be controlled by varying the siphon position height or depth between the first end 32 and second ends 34 in the server racks 22 in the above the water line situation. In some embodiments, the cooling flow of water can be adjusted for each rack 22 independently to meet unique rack heating needs, such as by adjusting a vertical position of a second end 34 of a conduit 38 passing by or embedded in the rack 22. In some embodiments, only a cooling basin 36 containing water from the body of water 12 is used for cooling. In others, only the conduits 38 are used. In still others, both a cooling basin 36 and conduits 38 are used. The water from the siphon 30 may feed a cold-water distribution system 40. Also, multiple siphons 30 can be used with each one individually cooling a server rack 22 or group of server racks 22. The cold-water distribution system 40 may supply water to the conduits 38. Any number of techniques can be used to distribute the cold water to the heat source areas with gravity through a siphon effect.

When flow through the siphon 30 is initiated and cool air forms on the top of the cooling basin then a convection effect can be established and heat removal from the racks 22 may be advantageously achieved at minimal to no cost. The natural expelling of hot air by convection can be accomplished with cool air flowing through the server racks 22, cool air heated by the server racks 22 and then the heated air rising through simple holes in the deck 18 of the ship to more sophisticated venture tube approaches to draw out warm air. Much of the heat from the racks 22 may be absorbed by the convection processes and subsequently expelled to the outside air. Warm water in the cooling basin 36 may be expelled by means of a pump 42 to the outside of the ship environment, such as out an ascending channel 44 from the basin 36 to an outlet 46 defined by the hull, that may be below the waterline 20 but above the basin 36. Alternately the channel 44 can simply dump the warm water overboard above the water line 20.

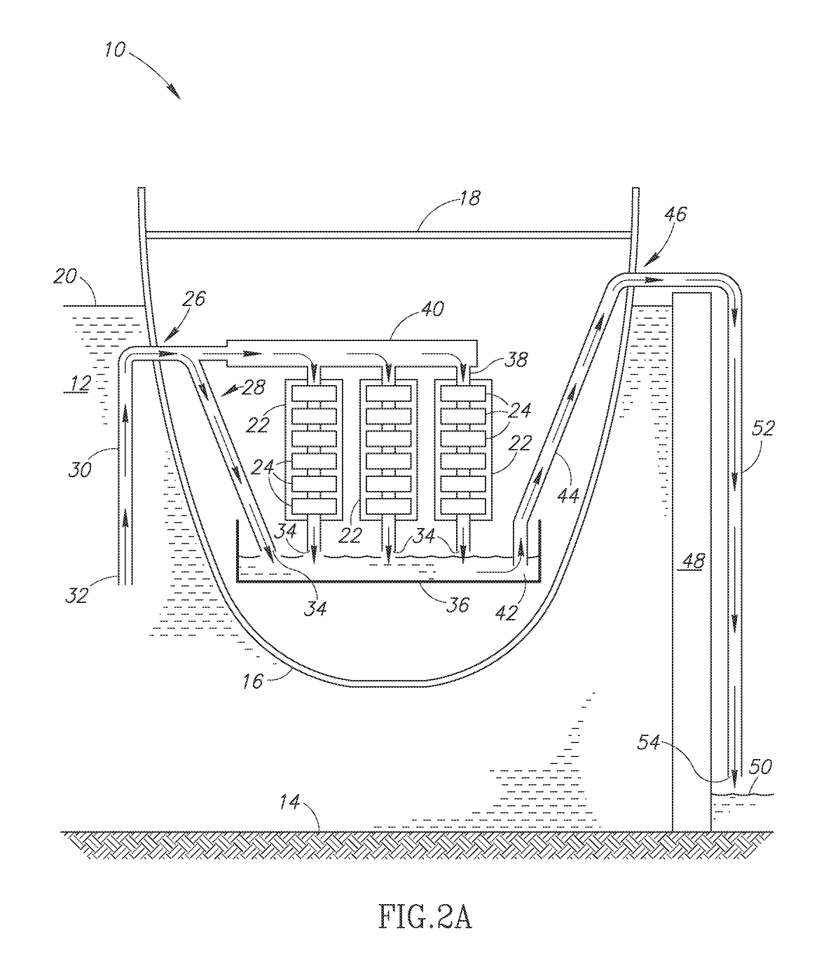

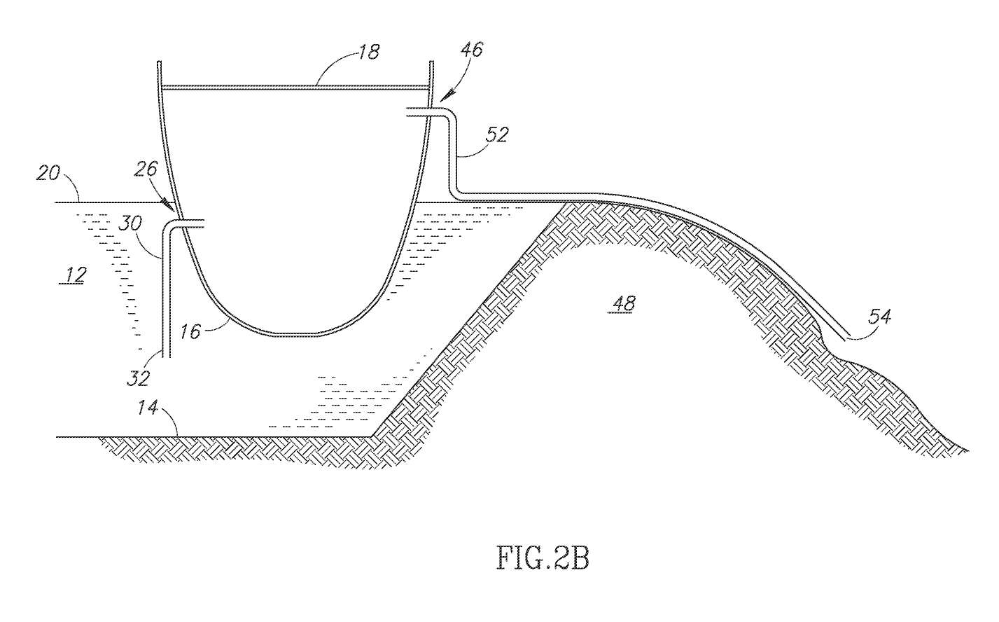

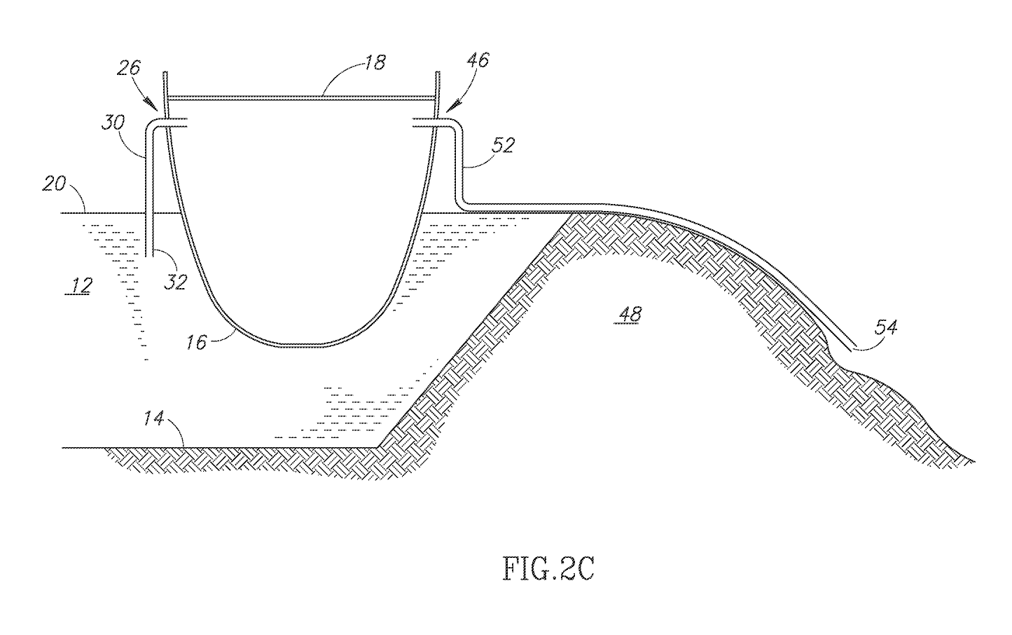

Referring to FIG. 2A the removal of heated water may be accomplished by means of a siphon effect by either locating the ship near a dam or building a partially or totally submerged structure near a dam where the similar fluid dynamic principles can be employed without the need of a ship. For example, a barrier 48 may contain the body of water 12 such that on one side of the barrier 48 no water is present or has a waterline 50 below the water line 20, and preferably below the waterline of water in the basin 36. This may be accomplished easily at any dam, at a lake or river near a waterfall, or other environment where a siphon pipe can reach a lower altitude than the basin 36.

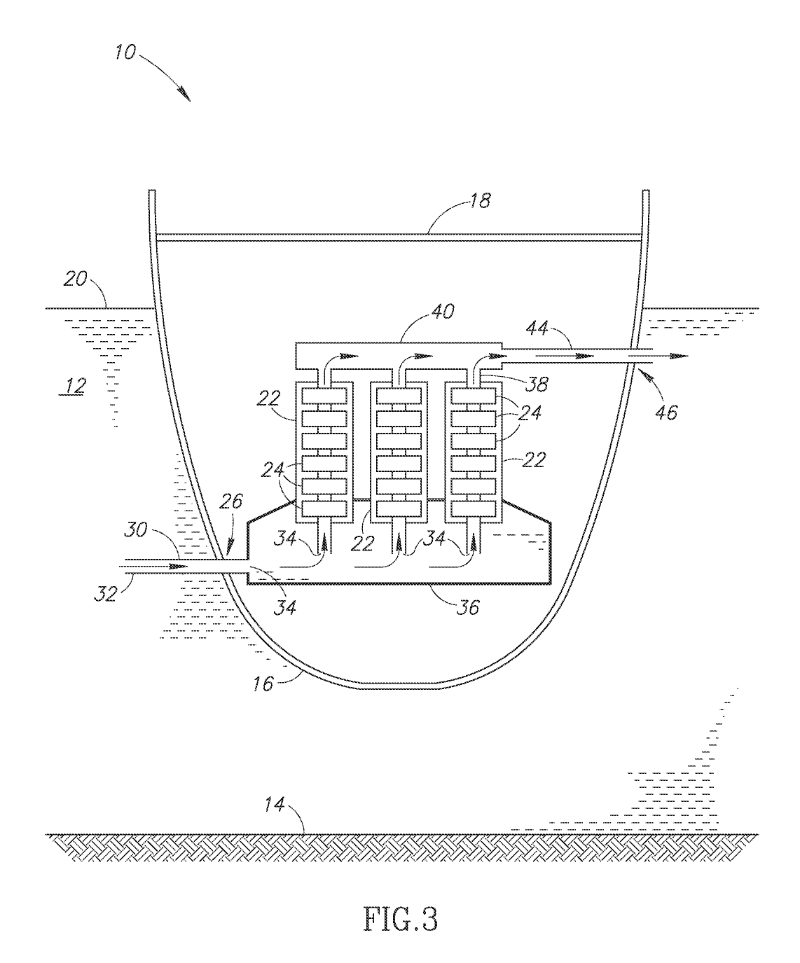

For example, as shown in FIG. 2A, the ascending channel 44 may be coupled to a descending channel 52 such that an end 54 of the descending channel 52 is below the basin 36. In some embodiments, the fluid path from the inlet 26 to the end 54 of the descending channel 52 is closed (see FIG. 3 for an example of “closed” path where the cooling basin 36 is sealed in the water path) such that as long as the end 54 is below the waterline 20, siphoning from the inlet 26, through the ship 10 (e.g. conduits 38), and out of the outlet 46 all occur due to passive siphoning. In a closed system, as water is drawn out of the basin 36 it reduces the water pressure after the servers which assists the flow of water into the data center through inlet 26. Adjusting the height of outlet 54 can be used to speed up or slow down the flow of water through the servers 22 in the closed system.

Referring to FIG. 2B which augments FIG. 2A, the descending channel 52 and end 54 may be positioned below the waterline 20 by positioning the descending channel 52 extending over a bank, stream bed, or other structure 48 adjacent the body of water 12 such that the end 54 is below the water line 20 and the waterline of any water in which the end 54 is located is also below the waterline 20. Similarly a trench or tunnel could be dug through 48 and the tube 52 routed through the trench or tunnel such that output 54 is below the water line 20.

In FIG. 2C the input tube 30 enters the hull above the water line. In this case the descending channel 52 extending over a bank, stream bed, or other structure 48 adjacent the body of water 12 such that the end 54 is below the siphon end 32 in a closed system or the basin 36 in an open system.

In all configurations shown in FIG. 2B or FIG. 2C, the end 54 could be adjustable to raise or lower its height, (in relation to some or all of the end 32 in a closed system, the basin 36 in an open system, and the water line 20) to control water flow. Similarly a trench or tunnel could be dug through a barrier 48 and the tube 52 routed through the trench or tunnel such that output 54 is below the end 32 in a closed system or the basin 36 in an open system.

In the above embodiments, siphoning may be initiated by pumping, such as by forcing water into an inlet of a siphon or creating a suction at an outlet of the siphon as known in the art. Once flow is created however, the pumping may cease and the pump itself may be removed for use elsewhere.

Referring to FIG. 3, in some embodiments, the flow of water cools the racks 22 of computing devices 24 by means of convective water flow. In particular, the inlet 26 may be positioned lower than the outlet 46. The path between the inlet 26 and outlet 46 may be closed, e.g. not open to the environment. For example, an inlet tube 30, that may or may not extend outwardly of the hull 16, may connect to the basin 36. The basin 36 is coupled to the tubes 38 in a closed manner. The distributor 40 is coupled to the tube 44 extending to the outlet 46, which may or may not descend or ascend with respect to the distributor 40. Inasmuch as the outlet 46 is positioned higher than the inlet 26, heating of fluid within the tubes 38 by the computing devices 24 will induce convective flow upward from the inlet 26 to the outlet 46. The configuration of FIG. 3 therefore advantageously discloses a completely passive approach to cooling a plurality of computing devices 24. In addition, the inlet tube 30 could be aimed against any existing water current in the body of water 12. In this way the water current pushing into the inlet 32 causes water pressure that drives water into the water basin 36. In a similar fashion the output tube 44 can be aimed to coincide with the current flow in the water 12 such that a venturi effect causes a suction effect pulling water from the outlet tube 44 through 46 and into the water environment 12. In addition a mechanical means can be placed on the inlet tube 30 and outlet tube 44 in the water environment 12 to amplify the effect of leveraging current movement within the body of water 12.

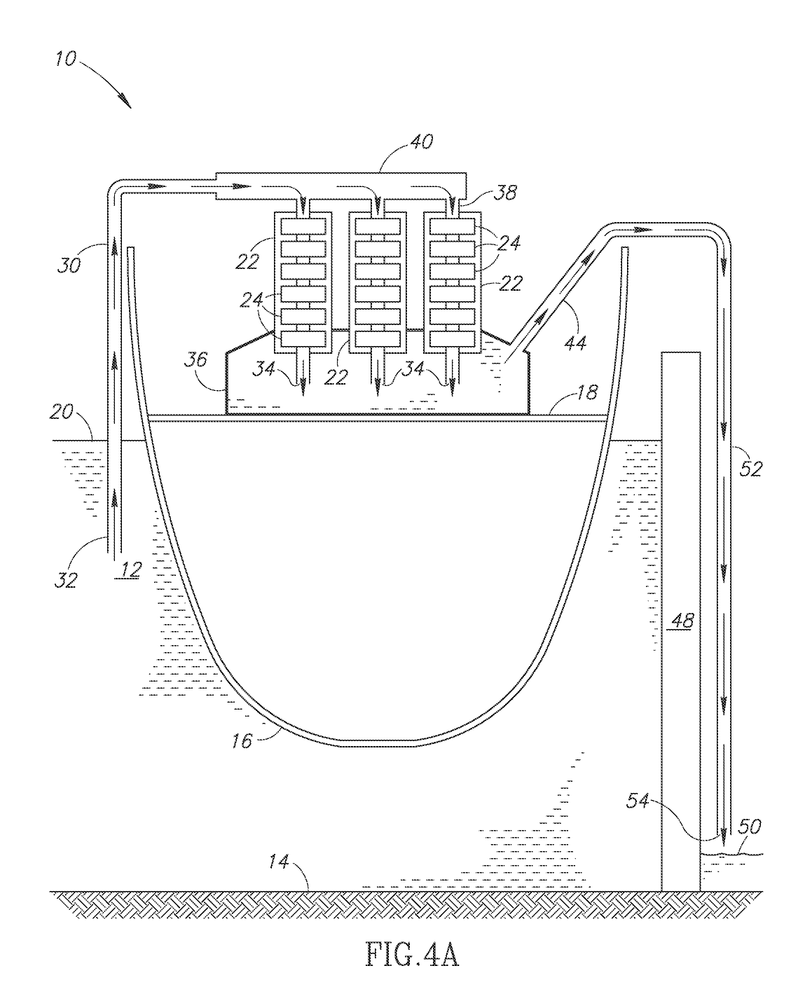

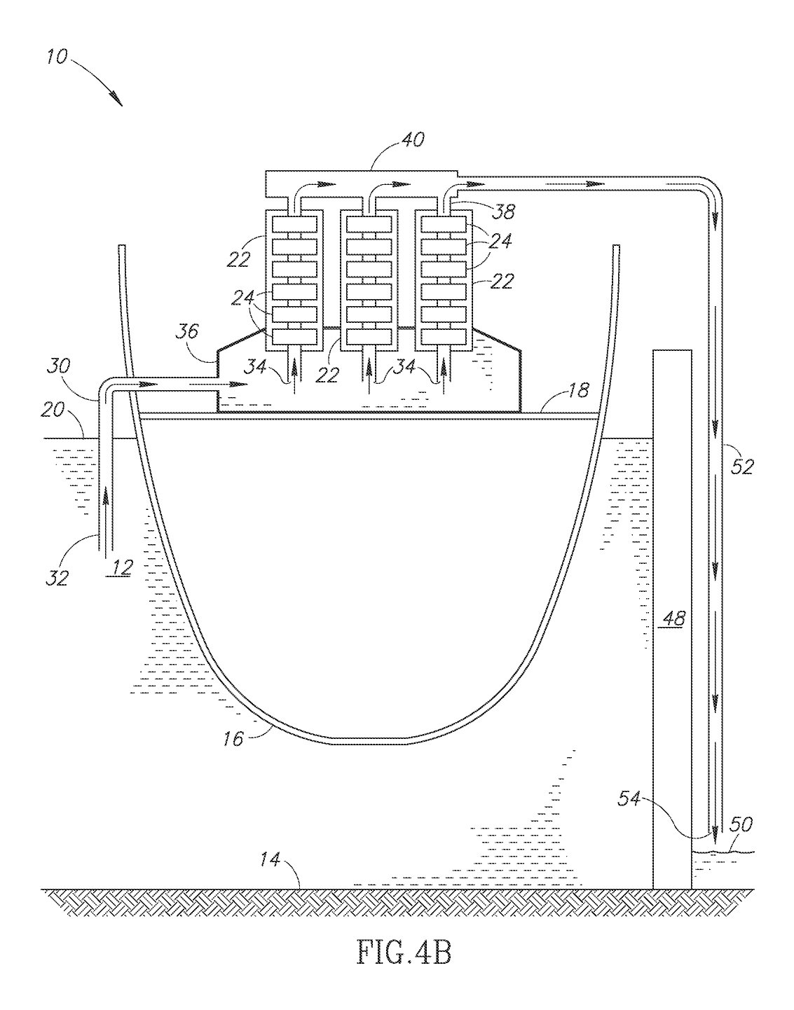

Referring to FIG. 4A, in some embodiments, some or all of the computing devices 24 and the corresponding tubes 38 are positioned above the waterline 20. In the illustrated embodiment, the basin 36 is also positioned above the waterline. In such embodiments, the fluid path from an opening 32 to an end 54 of a descending channel 52 may be completely or partially driven by gravity. To facilitate this, the fluid path between the end 32 of a tube 30 and end 54 of the descending channel 52 may be closed such that the pressure within the fluid path can be different from the surrounding air or water. For example, just like the embodiment of FIG. 3, the tubes 38 may connect to the basin 38 in closed manner. For the illustrated embodiment, the flow of water into the basin 36 from the output 34 of tubes 38 is partially assisted by the fall of water within the tubes 38. Likewise, the descending channel 52 draws water from the basin 36. In the illustrated embodiment of FIG. 4A, the end 54 of the descending channel 52 is below the water line 20, such as discussed above with respect to FIGS. 2A and 2B. Accordingly, the flow of water, once initiated, from end 32 of tube 30 to the end 54 of the descending channel 52 may be completely driven by gravity. Where the end 54 is positioned within the same body of water 12 or is above the waterline 20, then a pump, such as the pump 42 of FIG. 1 may be positioned at a point along the fluid path between end 32 and end 54, such as in or around the basin 36, in order to induce flow along the fluid path and overcome viscous losses.

Referring to FIG. 4B, in some embodiments in order to take advantage of convective flow due to heating of water, the inlet tube 30 may coupled to the basin 36 and the descending channel 52 may couple to the distributor 40. In this manner, the flow between end 32 and end 54 once initiated, from end 32 of tube 30 to the end 54 of the descending channel 52 may be completely driven by gravity and will be facilitated by convection due to heating.

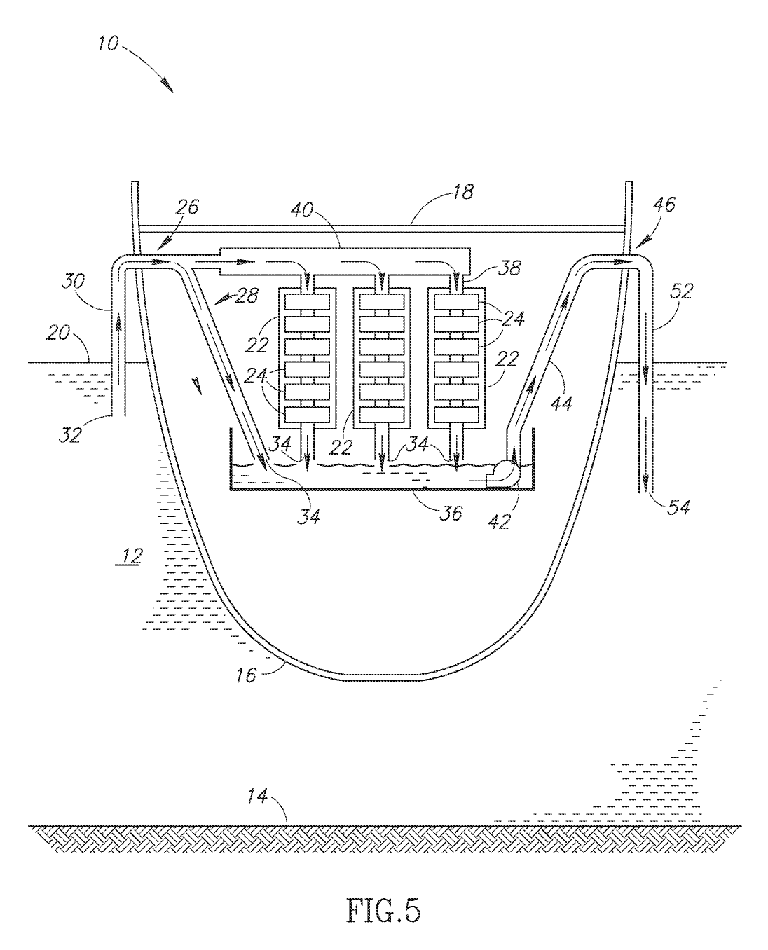

FIG. 5 illustrates an open system configuration wherein the inlet and outlet 26, 46 are positioned above the waterline 20 but the basin 36 is positioned below the waterline 20. In such embodiments, gravity fed siphoning between the end 32 and the ends 34 occurs once flow is initiated by some means. The end 32 may be higher than the ends 34 or lower than the ends 34 as long as the waterline 20 is above a water level in the basin 36. Inasmuch as the end 54 of the descending channel 52 in the embodiment of FIG. 5 is positioned in the same body of water 12, a pump 42 may be used to overcome the height difference between the water level in the basin 36 and the waterline 20. However, falling water within the descending channel 52 from the inlet 46 may assist in drawing water out of the basin 36. Alternatively, the descending channel 52 may extend along a barrier 48 as for the embodiments of FIGS. 2A through 2C in order to draw water out of the basin 36 by siphoning.

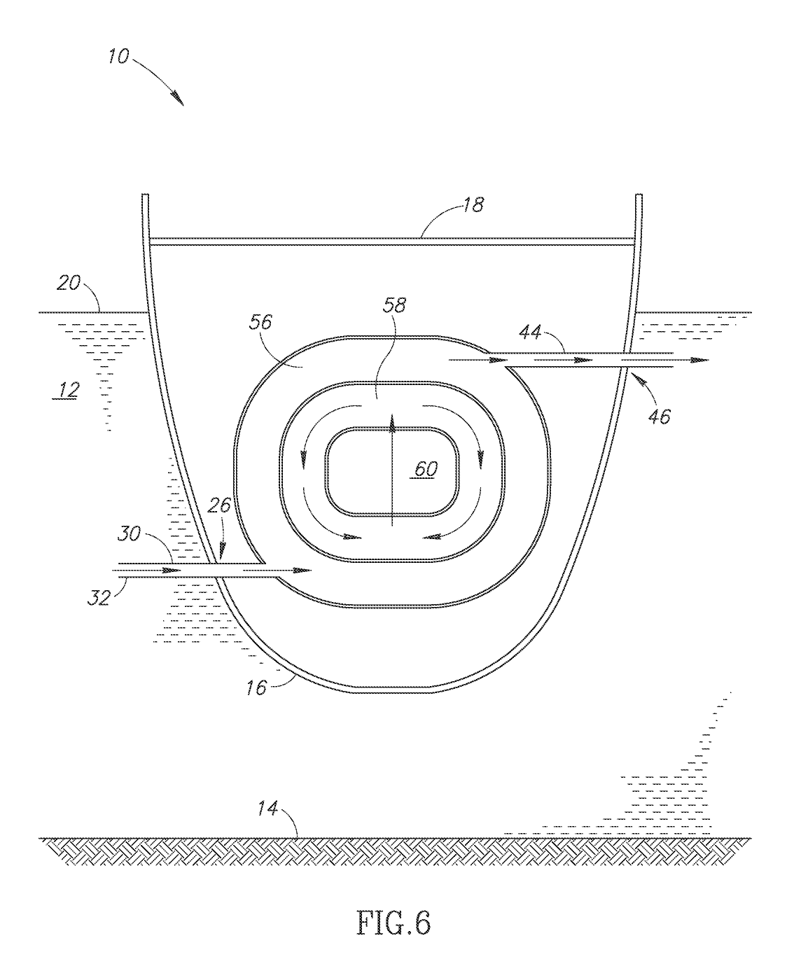

Referring to FIG. 6, in some embodiments, a fluid flow path 56 between the inlet 26 and outlet 46 through the hull 16 according to any of the methods disclosed herein may be maintained separate from a fluid flow path 58 around a heat source 60, such as the computing devices 24. For example, the fluid flow path 58 may define a convection driven path around or through the heat source 60. Likewise, the fluid flow path 56 may define a convection driven path between the inlet 26 and outlet 46 (e.g. FIG. 3). The fluid flow path 58 contain fresh water (e.g. deionized water) whereas the fluid flow path 56 contains water from the body of water 12, which may be salt water and less pure than the water of the fluid flow path 58. In some embodiments, the heat source 60 expels heat, e.g. by means of warm water, out its top part water into fluid flow path 58. Water in fluid flow path 58 warmed by this heat is cooled subsequently by the heat exchange boundary between the fluid flow path 58 and the fluid flow path 56. This cooling causes the water to get denser and flow down in both directions around the heat source 60. The water is continually cooled as it flows down while in contact with the heat exchanging wall with the fluid flow path 56. The water in the fluid flow path 56 is at its coldest as it re-enters the bottom of the heat source 60 to be heated up again, thereby forming a convention cycle.

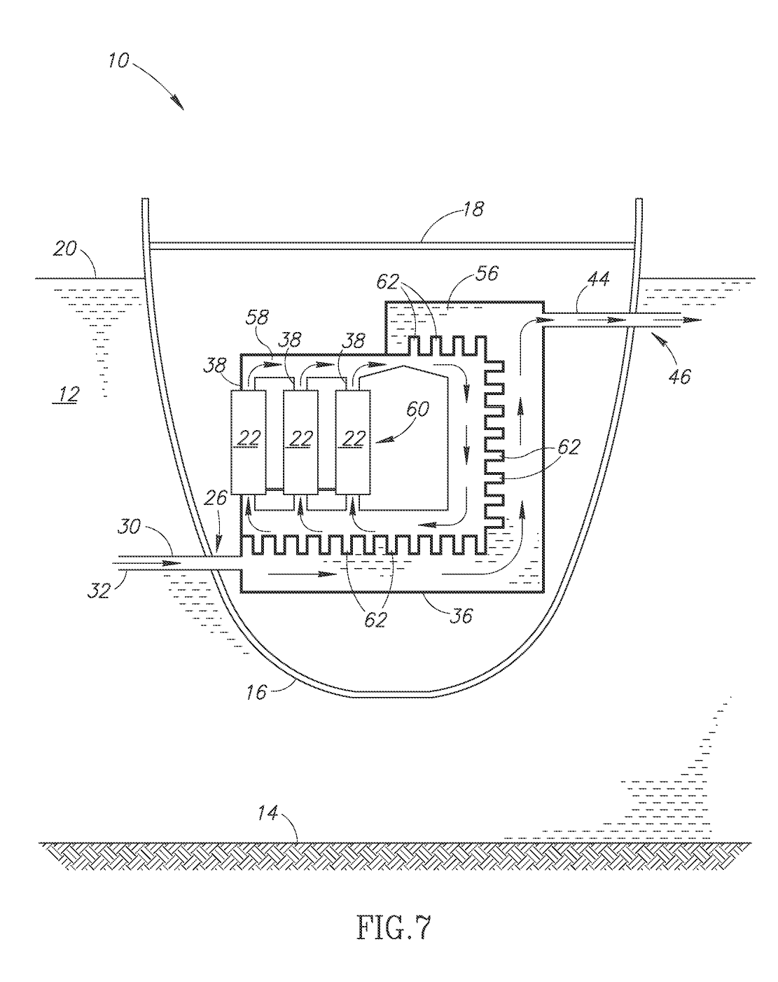

FIG. 7 illustrates a specific implementation of the concept of FIG. 6. In particular, fluid flow path 58 may connect to the bottom and top of the tubes 38 extending among the racks 22 or other configuration of computing devices 24 (shown in FIG. 3). Collectively the racks 22 may embody the heat source 60. An additional fluid flow path 56 may extend from inlet 26 to outlet 46 and pass adjacent to a portion of the fluid flow path 58 such that heat exchange takes place. For example, fins 62 may be defined at the boundary between the paths 56, 58 in order to promote heat exchange. In the illustrated embodiment, the ascending portion of the fluid path 58 is in contact with a heat source 60 and the descending portion is cooled when in contact with the fluid path 56. Since cooler water is denser and sinks and warmer water rises, natural convection is accomplished in the fluid flow path 58. Similarly the fluid flow path 56 is heated as it comes into thermal contact with the fluid in fluid flow path 58 via heat exchange methods such as fins 62. This causes water between the input 26 and output 46 to heat up and rise to be expelled at output 46 while new cold water is drawn in at input 26.

As is apparent in the foregoing description, embodiments are disclosed that provide completely gravity driven or passive water flow through a floating datacenter or any structure located in or near a body of water. Accordingly, operating costs associated with cooling the datacenter are low. The passivity and lack of moving parts further increases reliability of the cooling system and reduces the risk of catastrophic and non-catastrophic failures. In embodiments where the computing devices 24 are positioned below the waterline 20, the computing devices 24 may be completely or partially shielded from an electromagnetic pulse (EMP) by the water environment 12. In other embodiments the system could be designed such that a water environment completely surrounds the computing equipment to provide EMP shielding even if the computing equipment is above the water line. This could be done by filling a double hulled container that surrounds the computing equipment and using the water distribution path 40 as a top to the container. In some embodiments, the descending channels 28 and ascending channels 44 may be routed along the hull 16, such as between the walls of a double hull. The presence of water along the hull may also provide partial or complete protection from an EMP. In addition, although the structures cooled using the systems and methods disclosed herein are referred to as racks 22 and computing devices 24, any heat generating structure or device or any configuration of computing devices may be in contact with cooling water circulated according to the methods disclosed herein.

The present invention may be embodied in other specific forms without departing from its spirit or essential characteristics. The described embodiments are to be considered in all respects only as illustrative, and not restrictive. The scope of the invention is, therefore, indicated by the appended claims, rather than by the foregoing description. All changes which come within the meaning and range of equivalency of the claims are to be embraced within their scope.

What is claimed is:

1. A computing facility comprising:
a structure defining a waterline, a below-waterline portion, and an above-waterline portion;
a plurality of computing devices housed within the structure, the plurality of computing devices being coupled to a power source and in an operating state effective to generate heat;
an inlet positioned below the waterline;
an outlet in fluid communication with an exterior of the structure; and
a fluid path extending through the structure between the inlet and the outlet, the fluid path being configured to cool the plurality of computing devices.

2. The computing facility of claim 1, wherein the outlet is below the waterline and the inlet is positioned below the outlet effective to provide a convective path between the inlet and outlet responsive to heating of fluid within the fluid path.

3. The computing facility of claim 1, wherein at least a portion of the fluid path and at least a portion of the plurality of computing devices are positioned above the waterline.

4. The computing facility of claim 3, wherein the fluid path includes an ascending path extending from below the waterline to above the waterline, a descending path extending among the plurality of computing devices, and an exit path extending from a bottom of the descending path to the outlet.

5. The computing facility of claim 4, wherein the ascending path, descending path, and exit path are a closed path.

6. The computing facility of claim 5, further comprising an outlet tube coupled to the outlet and extending downwardly therefrom to below the waterline.

7. The computing facility of claim 4, further comprising a basin positioned to receive fluid from the descending path, the basin positioned below the waterline;
wherein the exit path extends from the basin to above the waterline and the exit path extends from above the waterline to below the waterline.

8. The computing facility of claim 7, wherein the basin is open.

9. The computing facility of claim 1, further comprising:
a basin positioned below the plurality of computing devices; and
a descending path extending from the inlet to the basin;
an ascending path extending from the basin to the outlet;
wherein the plurality of computing devices are located below the water line.

10. The computing facility of claim 9, wherein at least one of the descending path and the ascending path extends among the plurality of computing devices in thermal contact with the plurality of computing devices.

11. The computing facility of claim 10, further comprising a pump in fluid communication with the basin and configured to urge fluid from the basin through the ascending channel and out of the outlet.

12. The computing facility of claim 1, further comprising a descending channel, having a first end coupled to the outlet and a second end positioned below the waterline.

13. The computing facility of claim 1, wherein the computing devices are substantially shielded by the body of water from an electromagnetic pulse (EMP).

14. The computing facility of claim 1 wherein the fluid path is a passive fluid path providing high reliability and low cost of operation.

15. A method for operating a computing facility, the method comprising:
providing a floating structure defining a watertight hull;
placing the floating structure in a body of water such that a portion of the floating structure is below a waterline;
housing a plurality of computing devices in the floating structure;
operating the plurality of computing devices within the floating structure effective to generate thermal energy;
inducing a flow of water from the body of water into the hull;
inducing the flow of water to exit the hull; and
absorbing using the flow of water at least a portion of the thermal energy generated by the plurality of computing devices.

16. The method of claim 15, wherein the hull defines an inlet, an outlet, and a fluid path extending between the inlet and outlet, the outlet being higher than the inlet and the inlet and outlet being below the waterline, the method comprising:
heating fluid within the fluid path by means of the heat generated by the plurality of computing devices effective to induce convective flow from the inlet to the outlet.

17. The method of claim 16, wherein the plurality of computing devices are above the waterline, the inlet and outlet are above the waterline, and the fluid path is a closed path extending from the inlet to above the computing devices, down among the computing devices, and to the inlet.

18. The method of claim 17, wherein a barrier bounds the water on a first side thereof, the outlet being positioned on a second side of the barrier opposite the first side;
wherein one of no standing water is present on the second side of the barrier and a water level on the second side of the barrier is lower than the waterline; and
wherein inducing flow of water from the body of water into the watertight hull and inducing the flow of water to exit the hull comprises inducing a siphoning effect between the inlet and the outlet.

19. The method of claim 15, wherein:
at least a portion of the plurality of computing devices are above the waterline, an inlet siphon extends from below the waterline outside of the hull to an outlet below the waterline within the hull, the outlet emptying into a basin positioned below the waterline;
an outlet tube extends from an inlet positioned within the basin to an outlet positioned below the waterline;
wherein inducing the flow of water from the body of water into the hull comprises inducing siphoning through the inlet siphon.

20. The method of claim 19, wherein the outlet of the outlet tube is positioned to one side of a barrier, the body of water being positioned on an opposite side of the barrier;
wherein inducing the flow of water to exit the hull comprises inducing siphoning through the outlet siphon.
